(19) United States
(12) Patent Application Publication
(10) Pub. No.: US 2021/0151593 A1
(43) Pub. Date: May 20, 2021

(54) Process for Scaling a Gate Length

(71) Applicant: IMEC VZW, Leuven (BE)

(72) Inventors: Niamh Waldron, Heverlee (BE); AliReza Alian, Heverlee (BE); Uthayasankaran Peralagu, Aarschot (BE)

(21) Appl. No.: 16/950,519

(22) Filed: Nov. 17, 2020

(30) Foreign Application Priority Data
Nov. 18, 2019 (EP) 19209854.9

(51) Int. Cl. H01L 29/778; H01L 29/66

(52) U.S. Cl. CPC H01L 29/7786; H01L 29/66462

(57) ABSTRACT

A method comprising: providing a semiconductor structure including: a channel, a barrier, a non-conductive structure over the barrier, the non-conductive structure including a cavity having sidewalls separated by a first distance, providing a first non-conductive layer conformally over the non-conductive structure, thereby covering the sidewalls and the bottom surface of the cavity, etching the first non-conductive layer in such a way that it is removed from at least part of the bottom surface but still covers the sidewalls, etching through the bottom surface at most until the channel is reached, by using the first non-conductive layer covering the sidewalls as a mask, thereby forming an opening in the bottom surface of the non-conductive structure, the opening having sidewalls separated by a second distance, smaller than the first distance, and completely removing the first non-conductive layer.

### CROSS-REFERENCE TO RELATED APPLICATIONS

The present application is a non-provisional patent application claiming priority to European Patent Application No. 19209854.9, filed Nov. 18, 2019, the contents of which are hereby incorporated by reference.

### FIELD OF THE DISCLOSURE

The present disclosure relates to processes for forming a field-effect transistor (FET), an intermediate for the formation thereof, and to field-effect transistors obtained by such processes. The present disclosure includes examples that are suitable for forming high electron mobility transistors (HEMTs) or metal insulator semiconductor high electron mobility transistors (MIS-HEMTs) having a small gate length.

### BACKGROUND

In HEMT devices (e.g., GaN HEMT devices) used for radio frequency (RF) applications, one major goal is to increase the current-gain cutoff frequency (fT) and the maximum oscillation frequency (fMAX) to allow for operation at mm-wave frequencies and to improve efficiency. One of the key technology drivers for higher performance is to scale the gate length (Lg) to shorter values. Reducing Lg comes with numerous challenges. Currently, many HEMT devices (e.g., GaN devices) are processed on maximum 200 mm sized wafers where many fabrication processes are limited in how far Lg can be reduced just by conventional lithography. Also, although reducing Lg increases fT, it can also increase the gate resistance which would degrade fMAX. A shorter gate length also typically results in higher fields at the gate edges thereby increasing the gate leakage. Increased gate leakage increases power consumption and causes unwanted thermal heating of the devices when in the nominal “off state.”

Shinohara K. et al. (Journal of the National Institute of Information and Communications Technology, Vol. 51, Nos. 1/2, 2004, pages 95-102) described a process for the fabrication of sub-50 nm gate InP-HEMT by an advanced lithography method involving the use of electron beam lithography where a tri-layer resist and a metal lift-off was used. First, the top and middle resist layers were exposed simultaneously at a relatively low dose, then developed with a high-sensitivity developer; next, the bottom layer was exposed at a relatively high dose and developed with a low-sensitivity developer. The control of Lg was achieved by adjusting the exposure and development conditions for the bottom layer resist. The gate was then filled by evaporating the gate metal.

However, this method is very tedious, labor-intensive, and requires a very delicate tuning of the exposure and development conditions. Furthermore, this technology is hardly compatible with VLSI manufacturing methods used for 200 mm wafers and above. There is, therefore, a need in the art for simpler methods, for achieving small Lg in FETs in general and in HEMTs in particular.

### SUMMARY

The present disclosure includes examples for providing field-effect transistors, intermediates in the fabrication thereof, and processes for forming the same.

In a first aspect, the present disclosure relates to a process for forming an intermediate for the fabrication of a field-effect transistor, the process comprising the steps of:

a. Providing a semiconductor structure comprising:

i. a semiconductor channel layer,

ii. a barrier layer forming a heterojunction with the semiconductor channel layer, thereby creating a two-dimensional electron gas,

iii. a non-conductive structure over the barrier layer, the non-conductive structure comprising a cavity having sidewalls and a bottom surface, the sidewalls being separated by a first distance,

b. Providing a first non-conductive layer conformally over the non-conductive structure, thereby covering the sidewalls and the bottom surface of the cavity,

c. Etching the first non-conductive layer in such a way that it is removed from at least part of the bottom surface but still covers the sidewalls,

d. Etching through the bottom surface at most until the semiconductor channel layer is reached, by using the first non-conductive layer covering the sidewalls as a mask, thereby forming an opening in the bottom surface of non-conductive structure, the opening having sidewalls separated by a second distance, smaller than the first distance, and

e. Completely removing the first non-conductive layer.

In a second aspect, the present disclosure may relate to a process for fabricating a field-effect transistor comprising the process according to the first aspect, and further comprising the steps of:

Providing a gate in the cavity and the opening, and

Providing a source and a drain.

In a third aspect, the present disclosure relates to a field-effect transistor comprising:

a. Semiconductor channel layer and a barrier layer forming together a heterojunction creating a two-dimensional electron gas,

b. a dielectric layer comprising a cavity having sidewalls and a bottom surface belonging to the barrier layer,

c. a second non-conductive layer, over the dielectric layer, conformally covering the sidewalls and the bottom surface of the cavity, thereby narrowing cavity to form a narrower cavity and defining a first distance between the sidewalls of the narrower cavity,

d. an opening in a part of the second non-conductive layer present on the bottom surface of the cavity, the opening having sidewalls separated by a second distance, smaller than the first distance,

e. A source electrode and a drain electrode, over the barrier layer, and

f. A gate filling the cavity and the opening, and situated between the source electrode and the drain electrode.

It is a potential benefit of the processes of the first and second aspect that they allow Lg scaling without the need for advanced lithography.

It is a potential benefit of the processes of the first and second aspects that they do not require an atomic layer deposition for providing a gate metal in the opening. Indeed, the cavity can be made wide enough, and the opening can be made shallow enough, for the gate metal to fill the opening by simpler deposition methods such as physical vapor deposition, ionized physical vapor deposition, or chemical vapor deposition.

It is a potential benefit of the processes of the second aspect that the gate length can be made arbitrarily small without significant degradation of the gate resistance and hence Fmax. Indeed, the wider metal-filled cavity above the gate metal present in the opening permits to keep resistance low.

It is a potential benefit of embodiments of the different aspects of the present disclosure that the step present between the bottom of the cavity and the bottom of the opening can create non-conductive ledges on either side of the gate, thereby serving as gate edge termination suitable for reducing gate leakages. Examples of these ledges are shown in FIGS. 9, 16, 24, and 26 and are delimited by dashed lines in FIG. 27.

Aspects of the disclosure are set out in the accompanying independent and dependent claims. Features from the dependent claims may be combined with features of the independent claims and with features of other dependent claims as appropriate and not merely as explicitly set out in the claims.

The above and other characteristics of the present disclosure will become apparent from the following detailed description, taken in conjunction with the accompanying drawings, which illustrate, by way of example, the principles of the disclosure. This description is given for the sake of example only, without limiting the scope of the disclosure. The reference figures quoted below refer to the attached drawings.

### BRIEF DESCRIPTION OF THE FIGURES

The above, as well as additional, features will be better understood through the following illustrative and non-limiting detailed description of example embodiments, with reference to the appended drawings.

FIG. 1 is a schematic representation of a vertical cross-section through an assembly comprising a substrate, a buffer layer, a channel layer, according to an embodiment.

FIG. 2 is a schematic representation of a vertical cross-section through an intermediate in a process, according to an embodiment.

FIG. 3 is a schematic representation of a vertical cross-section through an intermediate in a process, according to an embodiment.

FIG. 4 is a schematic representation of a vertical cross-section through an intermediate, according to an embodiment.

FIG. 5 is a schematic representation of a vertical cross-section through an intermediate in a process, according to an embodiment.

FIG. 6 is a schematic representation of a vertical cross-section through an intermediate in a process, according to an embodiment.

FIG. 7 is a schematic representation of a vertical cross-section through an intermediate in a process, according to an embodiment.

FIG. 8 is a schematic representation of a vertical cross-section through an intermediate in a process, according to an embodiment.

FIG. 9 is a schematic representation of a vertical cross-section through an intermediate in a process, according to an embodiment.

FIG. 10 is a schematic representation of a vertical cross-section through an intermediate in a process, according to an embodiment.

FIG. 11 is a schematic representation of a vertical cross-section through an intermediate in a process, according to an embodiment.

FIG. 12 is a schematic representation of a vertical cross-section through an intermediate in a process, according to an embodiment.

FIG. 13 is a schematic representation of a vertical cross-section through an intermediate in a process, according to an embodiment.

FIG. 14 is a schematic representation of a vertical cross-section through an intermediate in a process, according to an embodiment.

FIG. 15 is a schematic representation of a vertical cross-section through an intermediate in a process, according to an embodiment.

FIG. 16 is a schematic representation of a vertical cross-section through an intermediate in a process, according to an embodiment.

FIG. 17 is a schematic representation of a vertical cross-section through an intermediate in a process, according to an embodiment.

FIG. 18 is a schematic representation of a vertical cross-section through an intermediate in a process, according to an embodiment.

FIG. 19 is a schematic representation of a vertical cross-section through an intermediate in a process, according to an embodiment.

FIG. 20 is a schematic representation of a vertical cross-section through an intermediate in a process, according to an embodiment.

FIG. 21 is a schematic representation of a vertical cross-section through an intermediate in a process, according to an embodiment.

FIG. 22 is a schematic representation of a vertical cross-section through an intermediate in a process, according to an embodiment.

FIG. 23 is a schematic representation of a vertical cross-section through an intermediate in a process, according to an embodiment.

FIG. 24 is a schematic representation of a vertical cross-section through an intermediate in a process, according to an embodiment.

FIG. 25 is a schematic representation of a vertical cross-section through an intermediate in a process, according to an embodiment.

FIG. 26 is a schematic representation of a vertical cross-section through an intermediate in a process, according to an embodiment.

FIG. 27 is an enlarged view of the vertical cross-section of FIG. 26.

In the different figures, the same reference signs refer to the same or analogous elements.

All the figures are schematic, not necessarily to scale, and generally only show parts which are necessary to elucidate example embodiments, wherein other parts may be omitted or merely suggested.

### DETAILED DESCRIPTION

Example embodiments will now be described more fully hereinafter with reference to the accompanying drawings. That which is encompassed by the claims may, however, be embodied in many different forms and should not be construed as limited to the embodiments set forth herein; rather, these embodiments are provided by way of example. Furthermore, like numbers refer to the same or similar elements or components throughout.

The present disclosure will be described with respect to particular embodiments and with reference to certain drawings but the disclosure is not limited thereto. The drawings described are only schematic and are non-limiting. In the drawings, the size of some of the elements may be exaggerated and not drawn on scale for illustrative purposes.

Furthermore, the terms first, second, third, and the like in the description and in the claims, are used for distinguishing between similar elements and not necessarily for describing a sequence, either temporally, spatially, in ranking or in any other manner. It is to be understood that the terms so used are interchangeable under appropriate circumstances and that the embodiments of the disclosure described herein are capable of operation in other sequences than described or illustrated herein.

Moreover, the terms top, bottom, over, under, and the like in the description and the claims are used for descriptive purposes and not necessarily for describing relative positions. It is to be understood that the terms so used are interchangeable under appropriate circumstances and that the embodiments of the disclosure described herein are capable of operation in other orientations than described or illustrated herein.

Reference throughout this specification to “one embodiment” or “an embodiment” means that a particular feature, structure or characteristic described in connection with the embodiment is included in at least one embodiment of the present disclosure. Thus, appearances of the phrases “in one embodiment” or “in an embodiment” in various places throughout this specification are not necessarily all referring to the same embodiment, but may. Furthermore, the particular features, structures or characteristics may be combined in any suitable manner, as would be apparent to one of ordinary skill in the art from this disclosure, in one or more embodiments.

Similarly, it should be appreciated that in the description of exemplary embodiments of the disclosure, various features of the disclosure are sometimes grouped together in a single embodiment, figure, or description thereof for the purpose of streamlining the disclosure and aiding in the understanding of one or more of the various inventive aspects. Rather, as the following claims reflect, inventive aspects lie in less than all features of a single foregoing disclosed embodiment. Thus, the claims following the detailed description are hereby expressly incorporated into this detailed description, with each claim standing on its own as a separate embodiment of this disclosure.

Furthermore, while some embodiments described herein include some but not other features included in other embodiments, combinations of features of different embodiments are meant to be within the scope of the disclosure, and form different embodiments, as would be understood by those in the art. For example, in the following claims, any of the claimed embodiments can be used in any combination.

Furthermore, some of the embodiments are described herein as a method or combination of elements of a method that can be implemented by a processor of a computer system or by other means of carrying out the function. Thus, a processor with the necessary instructions for carrying out such a method or element of a method forms a means for carrying out the method or element of a method. Furthermore, an element described herein of an apparatus embodiment is an example of a means for carrying out the function performed by the element for the purpose of carrying out the function.

In the description provided herein, numerous specific details are set forth. However, it is understood that embodiments of the disclosure may be practiced without these specific details. In other instances, well-known methods, structures, and techniques have not been shown in detail in order not to obscure an understanding of this description.

The disclosure will now be described by a detailed description of several embodiments of the disclosure. It is clear that other embodiments of the disclosure can be configured according to the knowledge of persons skilled in the art without departing from the technical teaching of the disclosure.

Reference will be made to transistors. These are devices having a first main electrode such as a drain, a second main electrode such as a source and a control electrode such as a gate for controlling the flow of electrical charges between the first and second main electrodes.

It will be clear for a person skilled in the art that the present disclosure is also applicable to similar devices.

In a first aspect, the present disclosure relates to a process for forming an intermediate for the fabrication of a field-effect transistor, the process comprising the steps of:

a. Providing a semiconductor structure comprising:

i. a semiconductor channel layer,

ii. a barrier layer forming a heterojunction with the semiconductor channel layer, thereby creating a two-dimensional electron gas,

iii. a non-conductive structure over the barrier layer, the non-conductive structure comprising a cavity having sidewalls and a bottom surface, the sidewalls being separated by a first distance,

b. Providing a first non-conductive layer conformally over the non-conductive structure, thereby covering the sidewalls and the bottom surface of the cavity,

c. Etching the first non-conductive layer in such a way that it is removed from at least part of the bottom surface but still covers the sidewalls,

d. Etching through the bottom surface at most until the semiconductor channel layer is reached, by using the first non-conductive layer covering the sidewalls as a mask, thereby forming an opening in the bottom surface of non-conductive structure, the opening having sidewalls separated by a second distance, smaller than the first distance, and

e. Completely removing the first non-conductive layer.

The process of the first aspect is compatible with the fabrication of any type of field-effect transistor. Indeed, although the semiconductor structure provided in step a. comprises a heterojunction, step d. of the first aspect allows etching through the bottom surface of the cavity until the semiconductor channel layer is reached. In such a case, the heterojunction is destroyed and the resulting field effect transistor is a metal-oxide semiconductor field-effect transistor (MOSFET). On another hand, if step d. is stopped before the semiconductor channel layer is reached, the heterojunction is maintained and the transistor is a high electron mobility transistor (HEMT).

Hence, in an embodiment, the etching in step d. may be stopped before the semiconductor channel layer is reached, and the field-effect transistor may be a high electron mobility transistor.

In some embodiments, the semiconductor structure provided in step a. comprises a semiconductor channel layer. The semiconductor channel layer is typically a III-V channel layer. The III-V channel layer may be for instance a InₓGa₁₋ₓAs channel layer or a GaN channel layer. In an example, it is a GaN channel layer.

In some examples, the thickness of the semiconductor channel layer may be 5 to 1000 nm.

In some embodiments, the semiconductor structure provided in step a. comprises a barrier layer. The barrier layer is such that it forms a heterojunction with the semiconductor channel layer, thereby creating a two-dimensional electron gas. For this purpose, the barrier layer is typically chosen to have a larger bandgap than the semiconductor channel layer. In the case of a GaN channel layer, a typical barrier layer would be an AlₓGa₁₋ₓN layer with an Al content (x) of from 5 to 40 at % or an InₓAl₁₋ₓN layer with an In content (x) of from 10 to 30 at %. Other barrier layers for a GaN channel layer are for instance InScAl barrier layers.

In any embodiment, the thickness of the barrier layer may be from 2 to 40 nm.

In any embodiment, a spacer layer can be present between the semiconductor layer and the barrier layer. The spacer layer may for instance be an AlN layer.

In any embodiment, the thickness of the spacer layer may be from 0.5 to 3 nm.

In general, step a. of providing the semiconductor structure may comprise providing the semiconductor structure on a substrate having a buffer layer thereon.

Hence, in any embodiment, step a. may comprise the steps of providing a substrate, providing a buffer layer on the substrate, and providing the semiconductor structure on the buffer layer.

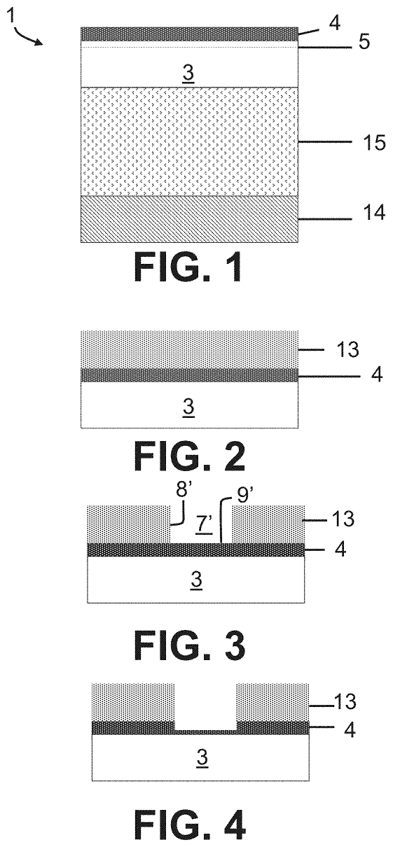

In any embodiment, as for instance illustrated in FIG. 1, step a. may comprise providing a substrate (14), providing a buffer layer (15) on the substrate (14), providing a semiconductor channel layer (3) on the buffer layer, providing a spacer layer on the channel layer (3), providing a barrier layer (4) on the spacer layer if present or on the channel layer (3), thereby creating a two-dimensional electron gas (5) in the semiconductor channel layer (3).

In FIGS. 2-5, a non-conductive structure (2) is then provided on the barrier layer (4) according to an embodiment.

In any embodiment, the substrate may be a semiconductor substrate such as a Si substrate, a SiC substrate, an AlN substrate, a GaAs substrate, an InP substrate, amongst others. In embodiments, the substrate may be a wafer having a diameter of 200 mm or more. For instance, it may be a Si wafer having a diameter of 200 mm or more.

In any embodiments where the substrate is Si and the channel layer is a GaN layer, the buffer layer may be an AlN layer, an AlₓGa₁₋ₓN layer, or a combination thereof. In embodiments, where the substrate is Si and the channel layer is a GaN layer, the buffer layer may comprise a bottom part, contacting the substrate, comprising an AlN layer, an AlₓGa₁₋ₓN layer, or a combination thereof, and an upper part, contacting the channel, comprising either a C-doped GaN layer or a Fe-doped GaN layer.

In any embodiment where the substrate is SiC and the channel layer is a GaN layer, the buffer layer may, for instance, be an AlN layer.

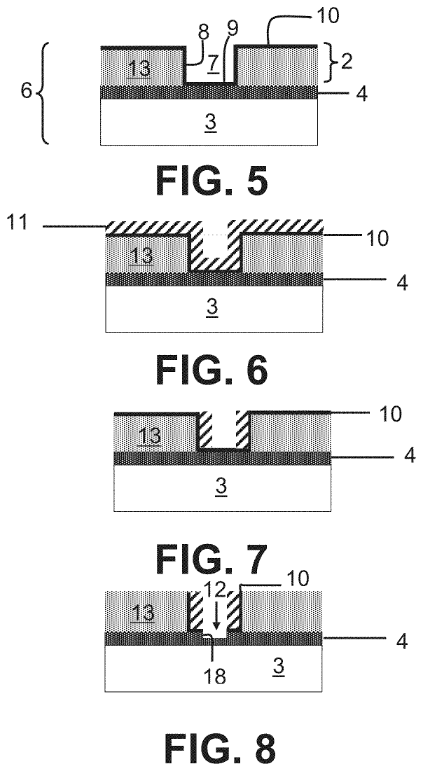

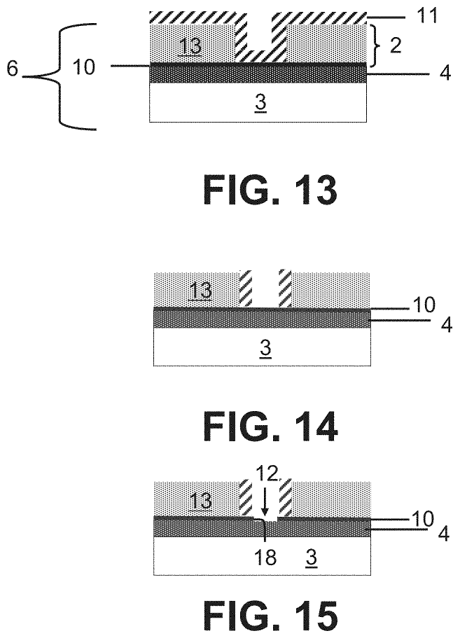

In any embodiment, the non-conductive structure provided in step a. may consist of a single layer or may comprise a plurality of layers. FIGS. 17 and 21 are examples where the non-conductive structure consists of a single layer. FIGS. 5 and 13 are examples where the non-conductive structure comprises a plurality of layers. In any case, the non-conductive structure comprises at least a dielectric layer. The dielectric layer may, for instance, be a silicon oxide layer or a silicon nitride layer. The dielectric layer may, for instance, have a thickness of from 50 to 1000 nm. The dielectric layer may be on the barrier layer, as for instance in FIGS. 5, 17 and 21 or may be over the barrier layer but separated therefrom by another layer (a second non-conductive layer), as for instance in FIG. 13.

In some embodiments, the dielectric layer comprises a cavity having sidewalls and a bottom surface. This cavity can be formed by lithography. Etching the dielectric layer to form the cavity may stop in the dielectric layer, as for instance in FIG. 17; on the barrier layer, as for instance in FIGS. 5 and 21; in the barrier layer, as for instance in FIG. 4; on the second non-conductive layer, as for instance in FIG. 13; or even on the channel layer (not depicted). When the etching stops in a particular layer, the formed cavity has its bottom surface belonging to that layer.

In any embodiment, the distance separating the sidewalls of this cavity may, for instance, be 50 to 1000 nm when the non-conductive structure will later be provided with a second non-conductive layer conformally on the dielectric layer, thereby narrowing the cavity to form a narrower cavity, as illustrated for instance in FIG. 5, before the performance of step b. Otherwise, when no such second non-conductive layer will be provided conformally on the dielectric layer, the distance separating the sidewalls of this cavity may, for instance, be 46 to 900 nm.

The cavity comprised in the dielectric layer is the cavity comprised in the non-conductive structure in the cases where the non-conductive structure does not comprise a second non-conductive layer on the dielectric layer. In such cases, as for instance depicted in FIGS. 13, 17, and 21, the distance separating the sidewalls of this cavity is the first distance. This first distance may be 46 to 900 nm.

When the non-conductive structure comprises a second non-conductive layer on the dielectric layer, however, as illustrated for instance in FIG. 5, the cavity present in the dielectric layer is not yet the cavity of non-conductive structure. In that case, the cavity of the non-conductive structure is the cavity present after the second non-conductive layer (having e.g., a thickness of from 2 to 50 nm) is conformally formed on the dielectric layer and the first distance may be 46 to 900 nm.

A first distance of 46 to 900 nm and a second distance, smaller than the first distance, can allow for gate length scaling while simultaneously allowing: the relatively easy filling of the cavity and the opening without requiring elaborate methods such as atomic layer deposition, good gate conductance and hence high maximum oscillation frequency, the creation of a step, and hence ledges, which can serve as gate edge termination, thereby reducing gate leakage.

In some of the illustrative embodiments that will now be presented, a second non-conductive layer is used. This second non-conductive layer can be a semi-conductive layer or a dielectric layer. If it is a semi-conductive layer, it can be a layer having a bandgap of at least 3 eV. Examples of suitable dielectric layers are silicon oxide, silicon nitride, aluminum oxide, and hafnium oxide. The second non-conductive layer is made of a material that can be etched selectively with respect to the first non-conductive layer used in step b. The first and the second non-conductive layers are therefore made of different materials. This permits the etching step c. to be performed selectively. The thickness of the second non-conductive layer may be 2 to 50 nm. The use of this second non-conductive layer can allow the height of the sidewalls of the opening to be tailored in the range of 2 to 50 nm by using a second non-conductive layer of corresponding thickness and by stopping the etching step d. on the layer directly underlying the second non-conductive layer.

In a first illustrative embodiment shown in FIG. 5, the non-conductive structure (2) provided in step a. may be formed of—a dielectric layer (13) comprising a cavity (7′, see FIG. 3) having sidewalls (8′) and a bottom surface (9′) belonging to the barrier layer (4), and—a second non-conductive layer (10), over the dielectric layer (13), conformally covering the sidewalls (8′) and the bottom surface (9′) of the cavity (7′), wherein the first non-conductive layer (11) provided in step b. is provided on the second non-conductive layer (10).

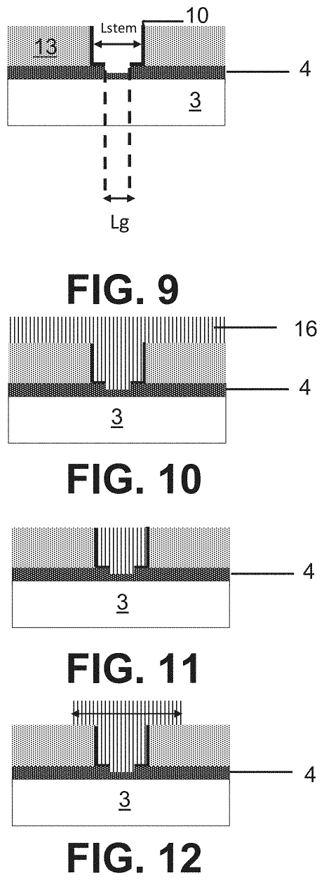

We now refer to FIGS. 2 to 4 where the formation of the non-conductive structure (2) of this embodiment is detailed. It may comprise the following steps. First, a dielectric layer (13) is provided over (and typically on) the barrier layer (4). Next, a cavity (7) is formed in the dielectric layer (13), stopping either on the barrier layer (4) (FIG. 3), in the barrier layer (4) (FIG. 4), or on the channel layer (3) (not depicted). We now refer to FIG. 5 where the second non-conductive layer (10) is provided over, and typically on the dielectric layer (13). This completes the non-conductive structure (2). The cavity (7) of the non-conductive structure (2) has sidewalls (8) made of the second non-conductive layer (10) and a bottom surface (9) which is also made of the second non-conductive layer (10). These sidewalls (8) are separated by the first distance (Lstem, see FIG. 9).

The height of the sidewalls of the opening can be tailored by using a second non-conductive layer of corresponding thickness. Furthermore, the opening is at least partially formed in the second non-conductive layer. When the second non-conductive layer is made of a dielectric material, the material forming the sidewalls of the opening, and which will serve as gate edge termination, is at least in part a dielectric material. Consequently, gate leakage will be relatively small.

In an embodiment, depicted in FIG. 13 which shows the situation after step b., the non-conductive structure (2) provided in step a. is formed of: a dielectric layer (13) comprising a cavity (7) having sidewalls (8) and a bottom surface (9), and a second non-conductive layer (10) between the barrier layer (4) and the dielectric layer (13), and wherein the bottom of the cavity (7) belongs to a top surface of the second non-conductive layer (10).

The formation of the non-conductive structure of this second illustrative embodiment is not depicted but may comprise the following steps. First, the second non-conductive layer is provided on the barrier layer. Second, a dielectric layer is provided on the second non-conductive layer. Next, a cavity is formed in the dielectric layer, stopping on the second non-conductive layer.

The height of the sidewalls of the opening can be tailored by using a second non-conductive layer of corresponding thickness. Furthermore, the opening is at least partially formed in the second non-conductive layer. When the second non-conductive layer is made of a dielectric material, the material forming the sidewalls of the opening, and which will serve as gate edge termination, is at least in part made of a dielectric material. Consequently, gate leakage will be relatively small.

In an embodiment, depicted in FIG. 17 which shows the situation after step b., the non-conductive structure (2) provided in step a. is formed of a single dielectric layer (13) comprising a cavity (7) having sidewalls (8) and a bottom surface (9) belonging to the single dielectric layer (13).

The formation of the non-conductive structure of this embodiment is not depicted but may comprise the following steps. First, a dielectric layer is provided on the barrier layer (as in FIG. 2). Next, a cavity is formed in the dielectric layer, stopping before reaching the barrier layer, i.e. stopping in the dielectric layer. This embodiment generally does not require a first non-conductive layer. However, instead, an etch can be advantageous if a precise height for the opening sidewalls is desired. Furthermore, the opening is at least partially formed in the dielectric layer. As a result, the material forming the sidewalls of the opening, and which will serve as gate edge termination, is at least in part a dielectric material. Consequently, gate leakage will be relatively small.

In an embodiment, depicted in FIG. 21 which shows the situation after step b., the non-conductive structure (2) provided in step a. is formed of a single dielectric layer (13) comprising a cavity (7) having sidewalls (8) and a bottom surface (9) which belong to the barrier layer (4). For instance, the bottom surface (9) of the cavity (7) may be the top surface of the barrier layer (4).

The formation of the non-conductive structure of this embodiment is depicted in FIGS. 2-4 and comprises the following steps. First, a dielectric layer is provided on the barrier layer (as shown in FIG. 2). Next, a cavity is formed in the dielectric layer, stopping on the barrier layer (as shown in FIG. 3) or in the barrier layer (see FIG. 4).

This embodiment generally does not require a first non-conductive layer. However, it can involve an etch if a precise height for the opening sidewalls is desired. Furthermore, the opening is entirely formed in the barrier layer, which is a semiconductor layer. As a result, the material forming the sidewalls of the opening, and which will serve as gate edge termination, is a semiconductor material. Consequently, gate leakage might be higher than for the three other illustrative embodiments.

Embodiments of the disclosure include a step b. of providing a first non-conductive layer (11) conformally over the non-conductive structure (2), thereby covering the sidewalls (8) and the bottom surface (9) of the cavity (7) (see FIGS. 6, 13, 17, and 21).

In some embodiments, this step c. may optionally comprise performing an anisotropic dry etch of the first non-conductive layer selectively with respect to the non-conductive structure.

This first non-conductive layer can be a semi-conductive layer or a dielectric layer. It can also be a dielectric layer. Examples of suitable dielectric layers are silicon oxide, silicon nitride aluminum oxide, and hafnium oxide. The thickness of the first non-conductive layer may be 50 to 200 nm.

Embodiments of the disclosure comprise a step c. of etching the first non-conductive layer (11) in such a way that it is removed from at least part of the bottom surface (9) but still covers the sidewalls (8).

In tan embodiment, this step is depicted in FIG. 7 where the etching is performed until the second non-conductive layer (10), present at the bottom of the cavity (7), is exposed.

In an embodiment, this step is depicted in FIG. 14 where the etching is performed until the second non-conductive layer (10), present at the bottom of the cavity (7), is exposed.

In an embodiment, this step is depicted in FIG. 18 where the etching is performed until the dielectric layer (13), present at the bottom of the cavity (7), is exposed.

In an embodiment, this step is depicted in FIG. 22 where the etching is performed until the barrier layer (4), present at the bottom of the cavity (7), is exposed.

Embodiments of the disclosure comprise a step d. of etching through the bottom surface (9) of the cavity (7) at most until the semiconductor channel layer (3) is reached, by using the first non-conductive layer (11) covering the sidewalls (8) as a mask, thereby forming an opening (12) in the bottom surface (9) of non-conductive structure (2), the opening (12) having sidewalls (18) separated by a second distance (Lg), smaller than the first distance (Lstem). This etching is typically anisotropic, as for instance depicted in the figures. This etching can be stopped in a dielectric layer (13) (see for instance FIG. 25), on the barrier layer (4) (see for instance FIGS. 15 and 19), in the barrier layer (4) (see for instance FIGS. 8 and 23), or on the channel layer (3) (not depicted).

In an embodiment, this step is depicted in FIG. 8 where the etching is performed through the second non-conductive layer (10) at most until the channel layer is exposed. This step may stop in the second non-conductive layer (10), on the barrier layer (4), in the barrier layer (4) (as depicted in FIG. 8), or on the channel layer (3). If this step is stopped in the second non-conductive layer (10), and the second non-conductive layer (10) is a dielectric layer (13), the resulting structure is an intermediate (1) in the fabrication of a metal insulator semiconductor high electron mobility transistor.

In an embodiment, this step is depicted in FIG. 15 where the etching is performed through the second non-conductive layer (10) at most until the channel layer (3) is exposed. This step may stop in the second non-conductive layer (10), on the barrier layer (4) (as depicted in FIG. 15), in the barrier layer (4), or on the channel layer (3). If this step is stopped in the second non-conductive layer (10), and the second non-conductive layer (10) is a dielectric layer (13), the resulting structure is an intermediate (1) in the fabrication of a metal insulator semiconductor high electron mobility transistor.

In an embodiment, this step is depicted in FIGS. 19 and 25 where the etching is performed through the dielectric layer (13) at most until the channel layer (3) is exposed. This step may stop in the dielectric layer (13) (as depicted in FIG. 25), on the barrier layer (4) (as depicted in FIG. 19), in the barrier layer (4), or on the channel layer (3). If this step is stopped in the dielectric layer (13), the resulting structure is an intermediate (1) in the fabrication of a metal insulator semiconductor high electron mobility transistor.

In an embodiment, this step is depicted in FIG. 23 where the etching is performed through at least part of the barrier layer (4) and at most until the channel layer (3) is exposed. This step may stop in the barrier layer (4) (as depicted in FIG. 23) or on the channel layer (3).

Some embodiments comprise a step e. of completely removing the first non-conductive layer (11).

In an example, if this first non-conductive layer (11) is removed selectively with respect to the non-conductive structure (2), the barrier layer (4) is exposed, and the channel layer (3) is exposed.

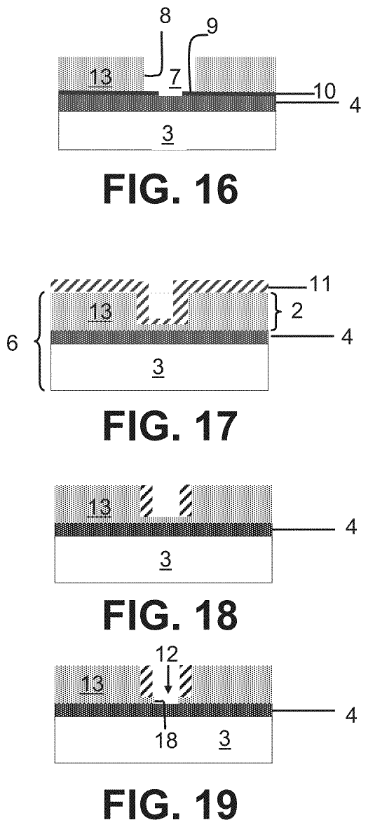

In embodiments where the second non-conductive layer (10) is present, the first non-conductive layer (11) is removed selectively with respect to the second non-conductive layer (10) (see FIGS. 9 and 16).

In an embodiment, this step is depicted in FIG. 9 where the first non-conductive layer (11) is removed selectively with respect to the second non-conductive layer (10) and the barrier layer (4). The structure depicted in FIG. 9 shows the first (Lstem) and the second (Lg) distances resulting from the method.

In an embodiment, this step is depicted in FIG. 16 where the first non-conductive layer (11) is removed selectively with respect to the second non-conductive layer (10), the dielectric layer (13), and the barrier layer (4).

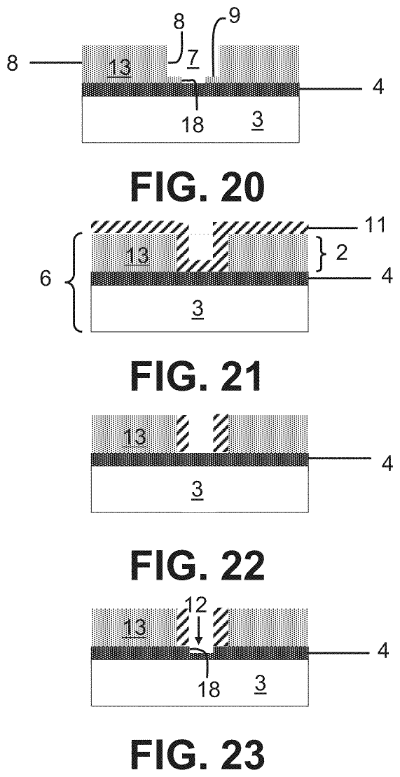

In an embodiment, this step is depicted in FIG. 20 where the first non-conductive layer (11) is removed selectively with respect to the dielectric layer (13) and the barrier layer (4).

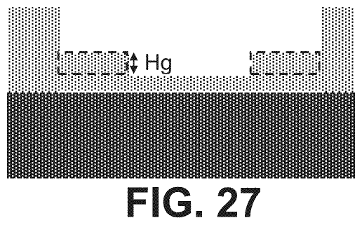

FIG. 26 shows an embodiment where the first non-conductive layer (11) is removed selectively with respect to the dielectric layer (13). FIG. 27 shows an enlarged portion of FIG. 26 where the height (Hg) of the opening sidewalls (18) is defined.

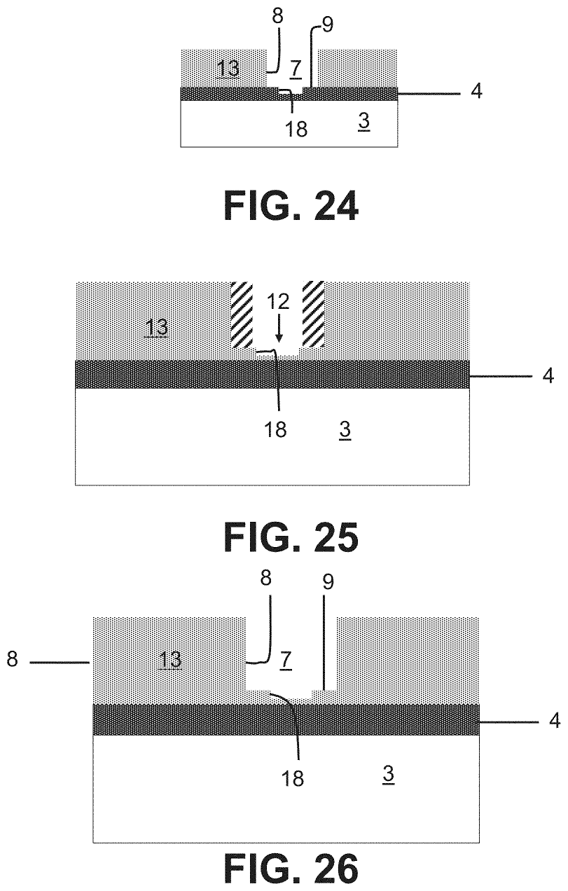

In an embodiment, this step is depicted in FIG. 24 where the first non-conductive layer (11) is removed selectively with respect to the dielectric layer (13) and the barrier layer (4).

In embodiments, the opening (12) may have sidewalls (18) having a height (Hg), measured perpendicularly to the bottom surface (9) of the non-conductive structure (2), of 2 to 50 nm, for example 2 to 20 nm. Such a height (Hg) can provide enough volume in the opening (12) to allow the formation of an efficient gate while simultaneously not being that high that the opening (12) cannot easily be filled.

In embodiments, the second distance (Lg) may be 1 to 500 nm, for example 10 to 100 nm. Such a distance can provide enough gate length. In embodiments, Lg may be 1 to 80% of Lstem, for example 20 to 80% of Lstem.

The disclosure may relate to a process for fabricating a field-effect transistor, and further comprising the steps of:

Providing a gate in the cavity and the opening, and

Providing a source and a drain.

Step f of providing a gate in the cavity and the opening typically comprises providing a gate metal in the cavity and the opening. In embodiments, it may further comprise lining the cavity and the opening with a gate dielectric before to fill them with a gate metal. In that last case, the field-effect transistor which is obtained is a metal insulator field-effect transistor; and if the obtained metal insulator field-effect transistor is a high electron mobility transistor (i.e. when step d stops before reaching the channel layer), it is a metal insulator semiconductor high electron mobility transistor. In embodiments, the thickness of the gate dielectric may be 1 to 40 nm. On another hand, when step f. does not further comprise lining the cavity and the opening with a gate dielectric before to fill them with a gate metal, the device obtained is a field-effect transistor, a high electron mobility field-effect transistor (in some embodiments where step d stops after reaching the barrier layer but before reaching the channel layer), or a metal insulator semiconductor high electron mobility field-effect transistor (e.g. when step d stops in a dielectric layer, e.g. in the second non-conductive layer, or in the dielectric layer).

This step is depicted in FIGS. 10-12.

First, the metal (16) is deposited in both the cavity (7) and the opening (12) (see FIG. 10). Second, the top surface of the metal (16) is recessed until the non-conductive structure (2) is exposed (see FIGS. 11 and 12). FIG. 11 shows an embodiment where the metal (16) is recessed by chemical mechanical planarization. FIG. 12 shows an embodiment where the metal layer is recessed by dry etching in such a way as to keep a metal cap of width larger than the first distance (Lstem) above the cavity (7). This has the potential advantage of still further decreasing the resistance.

The source and the drain are typically provided in step g. on either side of the gate.

The present disclosure relates to a field-effect transistor comprising

a. Semiconductor channel layer and a barrier layer forming together a heterojunction creating a two-dimensional electron gas,

b. a dielectric layer comprising a cavity having sidewalls and a bottom surface belonging to the barrier layer,

c. a second non-conductive layer, over the dielectric layer, conformally covering the sidewalls and the bottom surface of the cavity, thereby narrowing the cavity to form a narrower cavity and defining a first distance between the sidewalls of the narrower cavity,

d. an opening in a part of the second non-conductive layer present on the bottom surface of the cavity, the opening having sidewalls separated by a second distance, smaller than the first distance,

e. A source electrode and a drain electrode, over the barrier layer, and

f. A gate filling the cavity and the opening, and situated between the source electrode and the drain electrode.

It is to be understood that although embodiments, specific constructions, and configurations, as well as materials, have been discussed herein for devices according to the present disclosure, various changes or modifications in form and detail may be made without departing from the scope of this disclosure. For example, any formulas given above are merely representative of procedures that may be used. Functionality may be added or deleted from the block diagrams and operations may be interchanged among functional blocks. Steps may be added or deleted to methods described within the scope of the present disclosure.

While some embodiments have been illustrated and described in detail in the appended drawings and the foregoing description, such illustration and description are to be considered illustrative and not restrictive. Other variations to the disclosed embodiments can be understood and effected in practicing the claims, from a study of the drawings, the disclosure, and the appended claims. The mere fact that certain measures or features are recited in mutually different dependent claims does not indicate that a combination of these measures or features cannot be used.

What is claimed is:

1. A method for forming an intermediate for fabrication of a field-effect transistor, the method comprising:
providing a semiconductor structure comprising:
a semiconductor channel layer,
a barrier layer forming a heterojunction with the semiconductor channel layer, thereby creating a two-dimensional electron gas, and
a non-conductive structure over the barrier layer, the non-conductive structure comprising a cavity having sidewalls and a bottom surface, the sidewalls being separated by a first distance,
providing a first non-conductive layer conformally over the non-conductive structure, thereby covering the sidewalls and the bottom surface of the cavity,
etching the first non-conductive layer in such a way that it is removed from at least part of the bottom surface but still covers the sidewalls,
etching through the bottom surface at most until the semiconductor channel layer is reached, by using the first non-conductive layer covering the sidewalls as a mask, thereby forming an opening in the bottom surface of the non-conductive structure, the opening having sidewalls separated by a second distance, smaller than the first distance, and
completely removing the first non-conductive layer.

2. The method according to claim 1, wherein etching through the bottom surface comprises stopping the etching through the bottom surface before the semiconductor channel layer is reached and wherein the field-effect transistor is a high electron mobility transistor.

3. The method according to claim 2, wherein etching through the bottom surface comprises stopping the etching through the bottom surface before the barrier layer is reached and wherein the high electron mobility transistor is a metal insulator semiconductor high electron mobility transistor.

4. The method according to claim 1, wherein the bottom surface of the cavity belongs to the barrier layer.

5. The method according to claim 4, wherein the bottom surface of the cavity is a top surface of the barrier layer.

6. The method according to claim 1,
wherein the non-conductive structure is formed of:
a dielectric layer comprising a second cavity having sidewalls and a second bottom surface belonging to the barrier layer, and
a second non-conductive layer, over the dielectric layer, conformally covering the sidewalls and the second bottom surface of the cavity,
wherein the first non-conductive layer is provided on the second non-conductive layer.

7. The method according to claim 1, wherein the non-conductive structure is formed of:
a dielectric layer comprising the cavity having sidewalls and the bottom surface, and
a second non-conductive layer between the barrier layer and the dielectric layer, and wherein the bottom surface of the cavity belongs to a top surface of the second non-conductive layer.

8. The method according to claim 7, wherein the second non-conductive layer is made of a dielectric material.

9. The method according to claim 7, wherein the first non-conductive layer is made of a dielectric material.

10. The method according to claim 1, wherein the non-conductive structure is formed of a single dielectric layer comprising the cavity having sidewalls and the bottom surface belonging to the single dielectric layer.

11. The method according to claim 1, wherein the opening has sidewalls having a height, measured perpendicularly to the bottom surface of the non-conductive structure, of 2 to 50 nm.

12. The method according to claim 11, wherein the height is 2 to 20 nm.

13. The method according to claim 1, wherein the first distance is 46 to 900 nm.

14. The method according to claim 1, wherein the first distance is at least 10% larger than the second distance.

15. The method according to claim 1, wherein the second distance is 1 to 500 nm.

16. The method according to claim 15, wherein the second distance is 1 to 20 nm.

17. The method according to claim 1, further comprising:
providing a gate in the cavity and the opening, and
providing a source and a drain.

18. A field-effect transistor comprising
a semiconductor channel layer and a barrier layer forming together a heterojunction creating a two-dimensional electron gas,
a dielectric layer comprising a cavity having sidewalls and a bottom surface belonging to the barrier layer,
a second non-conductive layer, over the dielectric layer, conformally covering the sidewalls and the bottom surface of the cavity, thereby narrowing cavity to form a narrower cavity and defining a first distance between the sidewalls of the narrower cavity,
an opening in a part of the second non-conductive layer present on the bottom surface of the cavity, the opening having sidewalls separated by a second distance, smaller than the first distance,
a source electrode and a drain electrode, over the barrier layer, and
a gate filling the cavity and the opening and situated between the source electrode and the drain electrode.

19. The field-effect transistor according to claim 18, wherein the first distance is 46 to 900 nm.

20. The field-effect transistor according to claim 18, wherein the second distance is 1 to 500 nm.
